(19) United States
(12) Patent Application Publication
(10) Pub. No.: US 2007/0212865 A1
(43) Pub. Date: Sep. 13, 2007

(54) Method for planarizing vias formed in a substrate

(76) Inventors: Craig Amrine, Tempe, AZ (US); Owen Fay, Gilbert, AZ (US)

Correspondence Address: INGRASSIA FISHER & LORENZ, P.C. (FS), 7150 E. CAMELBACK ROAD, SUITE 325, SCOTTSDALE, AZ, 85251, US

(21) Appl. No.: 11/371,658

(22) Filed: Mar. 8, 2006

(51) Int. Cl. H01L 21/44

(52) U.S. Cl. 438/597

(57) ABSTRACT

A method for constructing an electronic assembly is provided. A substrate having first and second opposing surfaces and an integrated circuit formed therein is provided. A protective layer is formed over the first surface of the substrate. A via opening is formed through the protective layer and into the first surface of the substrate. A conductive via is formed in the via opening. The conductive via has an end at a first elevation relative to the first surface of the substrate. The end of the conductive via is ground such that the end of the conductive via is at a second elevation relative to the first surface of the substrate. The second elevation is less than the first elevation.

### FIELD OF THE INVENTION

The present invention generally relates to a method for planarizing vias formed in a substrate, and more particularly relates to a method for planarizing through-vias on a substrate with a die embedded therein.

### BACKGROUND OF THE INVENTION

Integrated circuit devices (i.e., integrated circuits) are formed on semiconductor substrates, or wafers. The wafers are then sawed into microelectronic die (or “dice”), or semiconductor chips, with each die carrying a respective integrated circuit. Each semiconductor chip is mounted to a package, or carrier, substrate using either wirebonding or “flip-chip” connections. The packaged chip is then typically mounted to a circuit board, or motherboard, before being installed in an electronic or computing system.

Before being installed, the circuit boards often require conductors (e.g., through-vias) to be formed therethrough so that electrical connections can be made from one side of the circuit board to the other. The formation of the conductive vias in printed-circuit-boards (PCB) typically involves laminating an organic resin board with copper foil and drilling vias through the foil and the board. The vias are then filled with the thick-film paste using stencil printing. After drying and curing, the excess via-fill material is planarized with a grinder. This planarization is typically performed by a relative rough grinding process, with little regard for its affect on the remainder of the surface of the circuit board. After grinding, the copper foil is then photo-etched into a specified pattern.

Recently, technologies have been developed which may reduce the need for conventional package substrates. One technology involves embedding a microelectronic die in a substrate with the “device” surface of the die being substantially co-planar with one of the surfaces of the substrate. Electrical connections can be made by forming conductors from the device surface of the die to other portions of the substrate. However, in some applications, conductive vias must be made through the substrate so that electrical connections can be made to the opposing side of the substrate. As with circuit boards, these vias must be planarized before additional processing steps can be performed. However, because the device surface of the die is exposed, the integrated circuit within the can be damaged if conventional planarization methods are used.

Accordingly, it is desirable to provide a method for effectively planarizing through-vias in a substrate with a surface of the substrate without risking damage to a die embedded within the substrate. Furthermore, other desirable features and characteristics of the present invention will become apparent from the subsequent detailed description of the invention and the appended claims, taken in conjunction with the accompanying drawings and this background of the invention.

### BRIEF DESCRIPTION OF THE DRAWINGS

The present invention will hereinafter be described in conjunction with the following drawing FIGs., wherein like numeral denote like elements, and

FIG. 1 is a top plan view of a device panel including a substrate and a plurality of microelectronic dice embedded therein;

FIG. 2 is a top plan view of a portion of the device panel of FIG. 1 illustrating the microelectronic dice in greater detail;

FIG. 3 is a cross-sectional side view of the device panel of FIG.2 taken along line 3-3;

FIG. 4 is a cross-sectional side view of the device panel of FIG. 3 with a protective layer formed over the upper and lower surfaces thereof;

FIG. 5 is a cross-sectional side view of the device panel of FIG. 4 with a polymeric layer formed over the protective layer;

FIG. 6 is a cross-sectional side view of the device panel of FIG. 5 with a plurality of via openings formed therethrough;

FIG. 7 is a cross-sectional side view of the device panel of FIG.6 with a plurality of conductive vias formed within the via openings;

FIG. 8 is a cross-sectional side view of the device panel of FIG. 7 illustrating the device panel undergoing a heating process;

FIG. 9 is a cross-sectional side view of the device panel of FIG. 8 after the polymeric layer has been removed from the protective layer;

FIGS. 10 and 11 are cross-sectional side views of the device panel of FIG. 9 with illustrating a device panel undergoing a grinding process;

FIG. 12 is a cross-sectional side view of the device panel FIG. 11 illustrating the grinding process in greater detail;

FIG. 13 is a cross-sectional side view of the device panel of FIG. 12 after the grinding process has been completed and the protective layer has been removed;

FIG. 14 is a cross-sectional side view of the device panel of FIG. 13 illustrating one of the via openings in greater detail;

FIG. 15 is a cross-sectional side view of the device panel of FIG. 13 after a shielding layer has been removed from the microelectronic die; and

FIG. 16 is a cross-sectional side view of the device panel of FIG. 15 illustrating the device panel undergoing a final heating process.

### DETAILED DESCRIPTION OF THE INVENTION

The following detailed description is merely exemplary in nature and is not intended to limit the invention or application and uses of the invention. Furthermore, there is no intention to be bound by any expressed or implied theory presented in the preceding technical field, background, brief summary, or the following detailed description. It should also be noted that FIGS. 1-16 are merely illustrative and may not be drawn to scale.

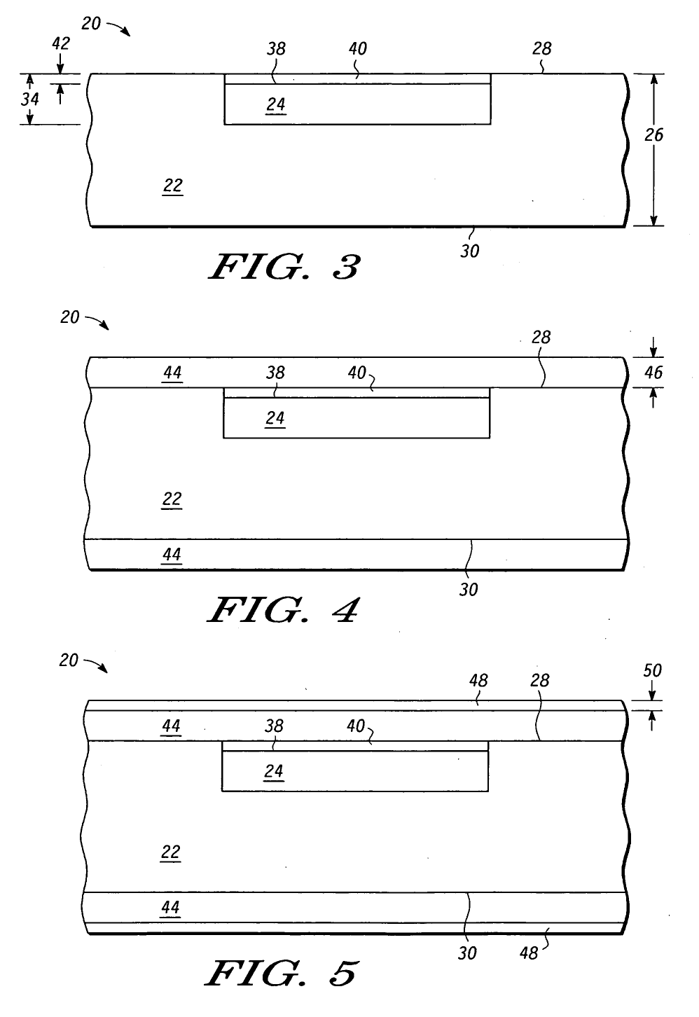

FIGS. 1-16 illustrate a method for forming an electronic assembly, according to one embodiment of the present invention. Referring to FIGS. 1, 2, and 3 there is illustrated a device panel 20. The device panel 20 includes a substrate 22 and a plurality of microelectronic dice 24. The substrate 22 is circular with a diameter of, for example, approximately 200 or 300 mm and a thickness 26 of approximately 0.65 mm. The substrate 22 also has an upper surface 28 and a lower surface 30 and may be made of, for example, a plastic material or epoxy. As shown in FIGS. 1 and 3, the microelectronic dice 24 are embedded within and uniformly distributed across the upper surface 28 of the substrate 22.

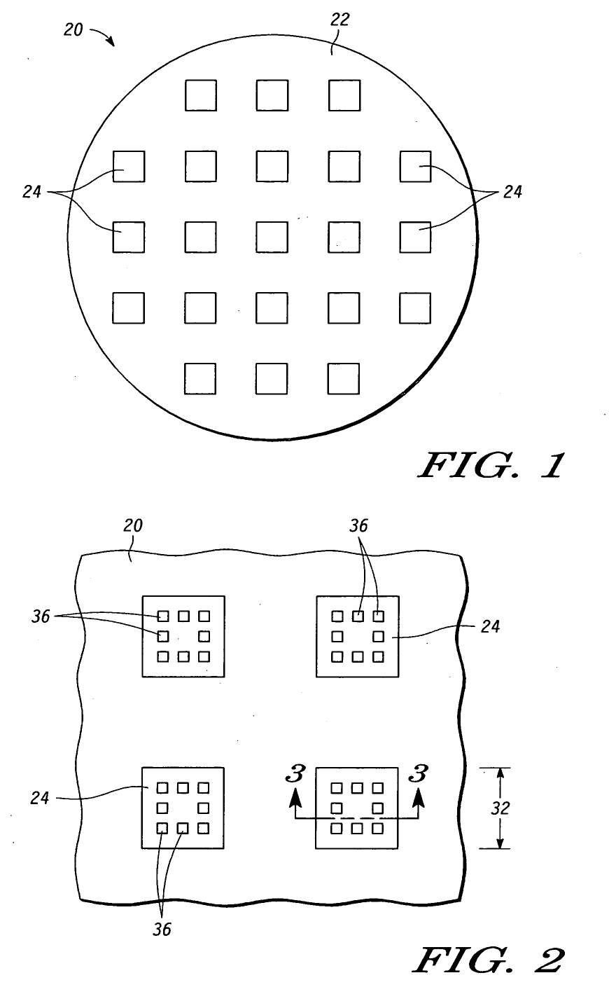

As shown in FIGS. 2 and 3, in one embodiment, the die 24 are substantially square (or rectangular) with a side length 32 of, for example, between 5 and 20 mm and a thickness 34 of, for example, between approximately 75 and 800 microns. Each of the microelectronic die 24 include a plurality of contact pads 36 formed on a device surface 38 and a shielding layer 40 formed over the device surface 38. Although not specifically illustrated, each of the microelectronic die 24 also includes an integrated circuit formed thereon, as is commonly understood in the art. As shown, a surface of the shielding layer 40 is co-planar, or congruent, with the upper surface 28 of the substrate 22. Although not specifically illustrated, the shield layer 40 has a thickness, for example, less than 10 microns such that device surface 38 of the microelectronic device 24 is at an elevation 42 of less than 10 microns below the upper surface 28 of the substrate 22. As such, particularly in an embodiment which does not include the shielding layer 40, the device surface 38 of the microelectronic dice 24 may be substantially co-planar with the upper surface 28 of the substrate 22. The shielding layer 40 may be, for example, made of photoresist or other organic polymer.

Although the following process steps may be shown as being performed on only one portion of the device panel 20, it should be understood that each of the steps may be performed on substantially the entire panel 20 simultaneously. As shown in FIG. 4, a protective layer 44 is first formed over the upper and lower surfaces 28 and 30 of the substrate 22. The protective layer 44 has, for example, a thickness 46 of between 5 and 20 microns over both the upper and lower surfaces 28 and 30 of the substrate 22. As shown the protective layer 44 also covers the microelectronic die 24. The protective layer 44 may be formed by dipping the entire device panel 20 into a container of semiconductor processing fluid and allowing the fluid to dry thereon. The protective layer 44 may be made of a soluble material. In one embodiment, the protective layer 44 is made from water soluble material, such as EMULSITONE 1146. EMULSITONE 1146 is available from Emulsitone Company of Whippany, N.J.

As illustrated in FIG. 5, a polymeric layer 48 is then formed over the protective layer 44 on both the upper and lower surfaces 28 and 30 of the substrate 22. The polymeric layer 48 is a polyimide tape and has a thickness of, for example, between 20 and 200 microns. In one embodiment, the thickness of the polymeric layer is approximately 35 microns.

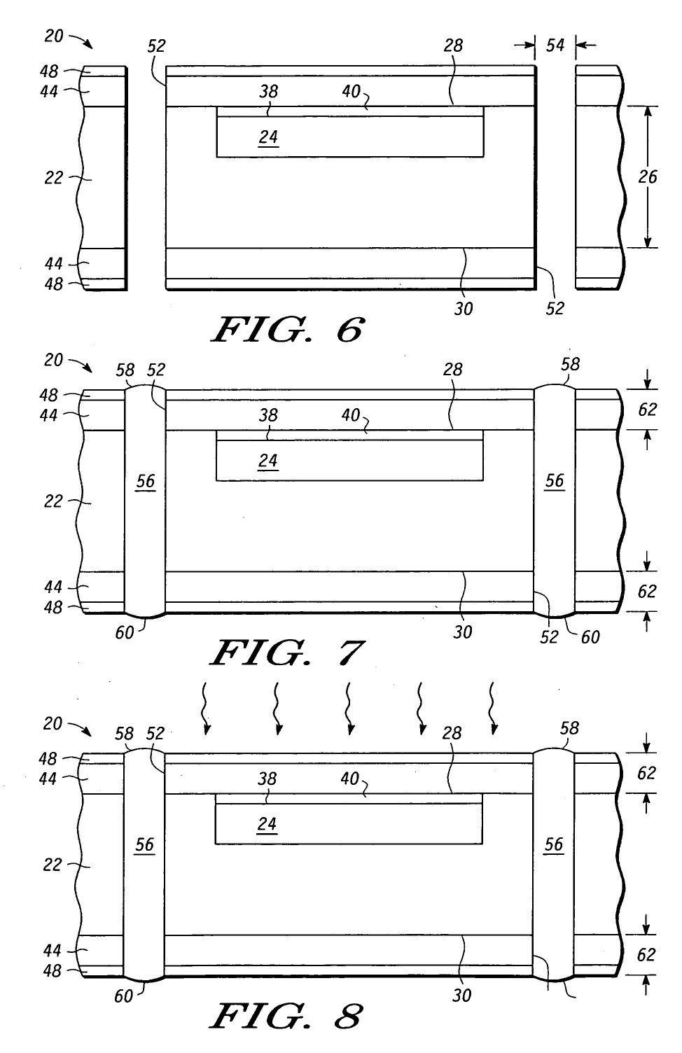

Next, as shown in FIG. 6, a plurality of via openings 52 are then formed through the polymeric layer 48 and the protective layer 44 over the upper surface 28 of the substrate 22, the substrate 22, and the protective layer 44 and the polymeric layer 48 over the lower surface 30 of the substrate 22. In one embodiment, the via openings 52 are formed on opposing sides of the microelectronic die 24 and have a width 54 of, for example, between 60 and 300 microns. The via openings 52 may be formed using a mechanical drill or electromagnetic radiation, such as ultraviolet or infrared laser light. The ratio of the thickness 26 of the substrate 22 to the width 54 of the via openings 52 may be, for example, between 6:1 and 10: 1.

Referring to FIG. 7, a plurality of conductive vias 56 (or “through-vias”) are then formed in the via openings 52. As illustrated, each of the conductive vias 56 fills a respective one of the via openings 52 and has upper end 58 and a lower end 60. As shown, the upper ends 58 of the conductive vias 56 extend above the polymeric layer 48 over the upper surface 28 of the substrate 22. The lower ends 60 of the conductive vias 66 extend below the polymeric layer 48 over the lower surface 30 of the substrate 22. The upper and lower ends 58 and 60 of the conductive vias 56 may lie at an elevation 62 relative to the upper and lower surfaces 28 and 30 respectively of the substrate 22. The elevation 62 may be similar to the combined thickness of the protective layer 44 and the polymeric layer 48. In one embodiment, the conductive vias 56 are formed in the via openings 52 by depositing a conductive paste into the via openings 52 using screen-printing, and the conductive paste may be made of, for example, a mixture of silver and copper.

As illustrated in FIG. 8, the device panel 20 then undergoes a heating process. In one embodiment, the device panel 20 is heated to a temperature of approximately 100° C. for approximately 30 minutes to partially cure, or dry, the conductive paste that forms the conductive vias 56. The heating process may be performed in an oven, as is commonly understood in the art.

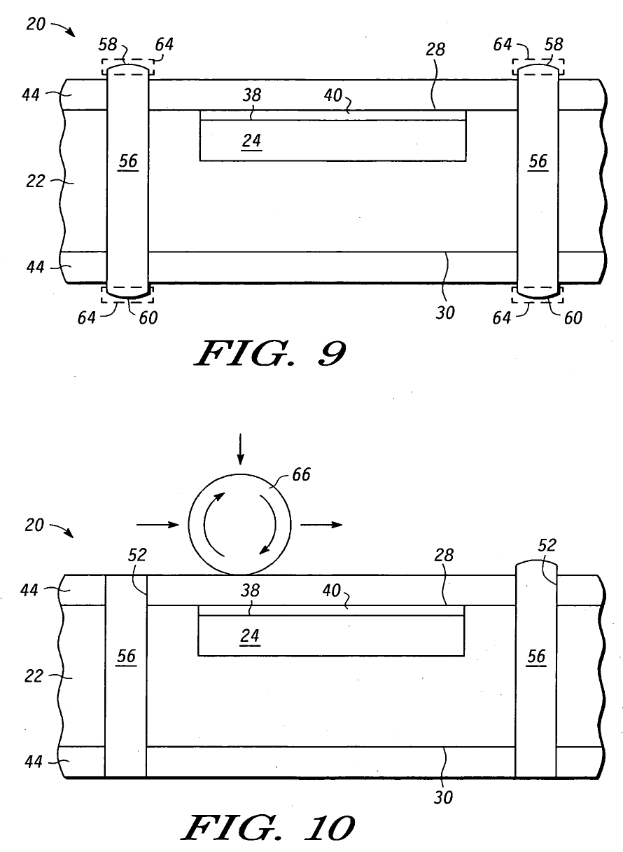

Referring to FIG. 9 in combination with FIG. 8, the polymeric layer 48 is then removed from over the protective layer 44 on both the upper and lower surfaces 28 and 30 of the substrate 22. As shown specifically in FIG. 9, after the polymeric layer 48 has been removed, the upper and lower ends 58 and 60 of the conductive vias remain substantially unchanged and form via bumps 64 which extend from the protective layer 44 over the upper and lower surfaces 28 and 30 of the substrate 22.

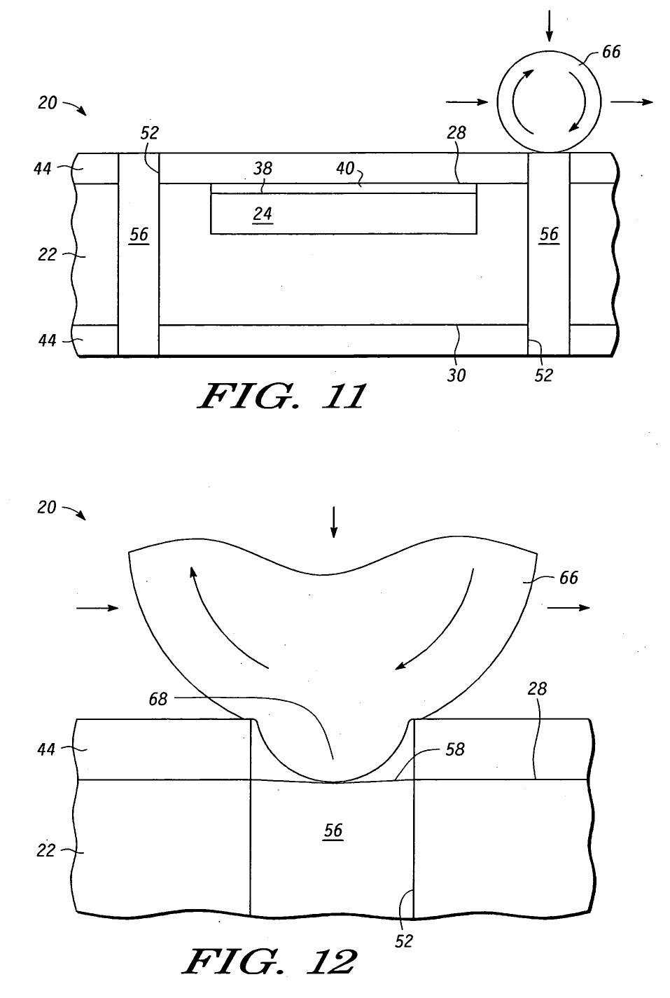

The device panel 20 then undergoes a grinding (and/or polishing and/or abrasion) process, as shown FIGS. 10 and 11. The grinding is performed using a polishing or grinding head 66 (or polishing element) which is placed in contact with and pressed against the protective layer 44 while being rotated and moved across the device panel 20. The grinding process may be a chemical-mechanical polishing (CMP), such as a dry CMP or a wet CMP using a non-aqueous solvent. As illustrated specifically in FIG. 12, the polishing head 66 may have a compliance, which when combined with the force with which the polishing head 66 is pressed against the device panel 20, causes a portion 68 of the polishing head 66 to protrude into the via openings 52 as the polishing head 66 is moved across the device panel 20. As shown in FIG. 12, the protruding portion 68 of the polishing head 66 grinds down the ends of the conductive vias 56 so the ends do not extend past the protective layer 44. In one embodiment, the conductive vias 56 are still “wet” during the grinding process.

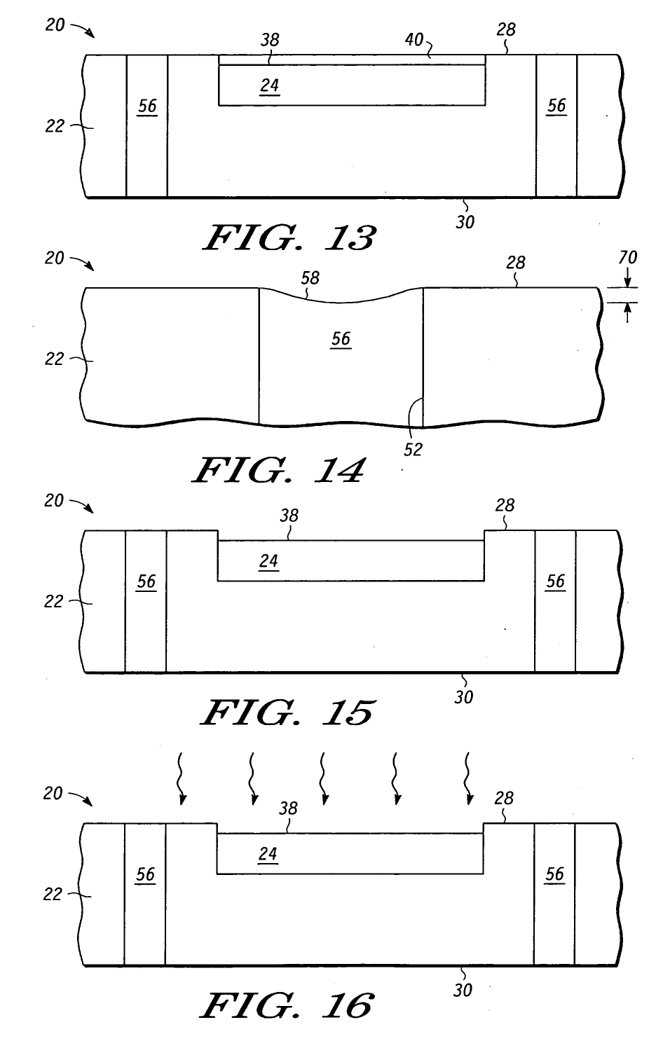

As illustrated in FIG. 13, after the grinding process is completed, the protective layer 44 is removed. In an embodiment in which the protective layer 44 is water soluble, the protective layer 44 may be removed by rinsing the upper and lower surfaces 28 and 30 of the substrate 22 with water for approximately 10 minutes. FIG. 14 illustrates an upper end of one of the conductive vias 56 after the grinding process has been completed and the protective layer 44 has been removed. As shown the upper ends 58 of the conductive vias 56 has experienced a “cupping” effect due to the protruding portion 68 of the polishing head 66, as illustrated in FIG. 12. Thus, as illustrate in FIG. 14, the upper ends 58 of the conductive vias 56 have a concave shape with a low portion thereof lying at an elevation 70 below the upper surface of substrate 22. The elevation 70 may be less than 10 microns below the upper surface 28. Although not specifically illustrated, it should be understood that the lower ends 60 of the conductive vias 56 may experience a similar effect with the “low” portions of he lower ends 60 lying at the elevation 70 “above” The lower surface 30 of the substrate 22.

As shown in FIG. 15, the shielding layer 40 is then removed from the device surface 38 of the microelectronic die 24. In the embodiment where the shielding layer 40 is made of photoresist, the shielding layer 40 may be removed using, for example, a n-methylpyrrolidone (NMP) solvent or acetone, as is commonly understood. In one embodiment, the shielding layer 40 is rinsed with the NMP solvent for 8 minutes and heated to a temperature of approximately 85° C.

Then, as shown in FIG. 16, the device panel 20 undergoes a final heating process to complete the curing of the conductive vias 56. In one embodiment, the device panel 20 is heated for approximately 60 minutes at a temperature of approximately 160° C.

After final processing steps, which may include the formation of various insulating layers and conductive traces formed on the upper and lower surfaces 28 and 30 of the substrate 22, which may be used to electrically connect the contact pads 36 as shown in FIG. 2 to the conductive vias 56 as shown in FIG.16. The device panel 20 may be sawed into individual packages, with each package carrying a respective microelectronic die 24, or multiple dice 24, as illustrated in FIG. 1. The individual packages may then be installed in various electronic and/or computing systems.

One advantage of the method described above is that because of the reduced thickness of the protective layer 44, the compliance of the polishing head 66, and the grinding process being carried out while the conductive vias are only partially cured, the planarization of the restrictive ends of the conductive vias can be more accurately controlled. As a result, the planarization of the conductive vias relative to the upper and lower surfaces of the substrate is improved. Therefore, subsequent processing steps, such as the formation of conductive traces between the microelectronic dice and the conductive vias, are facilitated.

Other embodiments may use different materials to form the protective layer, such as photoresist. The thickness of the protective layer may be varied by, for example, altering the viscosity of the fluid in which the panel is dipped to form the protective layer. A second protective layer may be formed over the initial protective layer, for example, by dipping the panel into the semiconductor processing fluid a second time. The thickness of the protective layer, along with the compliance of the polishing head, may be varied to control the amount of cupping experienced by the ends of the conductive vias. In this way, the exactness of the planarization can be varied for different specific applications. For example, if the thickness of the protective layer is further reduced, a less compliant polishing head may be used. The device panel may be different sizes and shapes, such as square with a side length of, for example, between 100 and 500 mm.

The invention provides a method for constructing an electronic assembly. A substrate having first and second opposing surfaces and an integrated circuit formed therein is provided. A protective layer is formed over the first surface of the substrate. A via opening is formed through the protective layer and into the first surface of the substrate. A conductive via is formed in the via opening. The conductive via has an end at a first elevation relative to the first surface of the substrate. The end of the conductive via is ground such that the end of the conductive via is at a second elevation relative to the first surface of the substrate. The second elevation is less than the first elevation.

The protective layer may have a thickness less than 35 microns. The thickness of the protective layer may be between approximately 5 and 20 microns.

The grinding of the end of the conductive via may include grinding the protective layer. The grinding may be performed with a polishing element having a compliance, and the polishing element may apply a force onto the protective layer wherein the compliance and the force are such that a portion of the polishing element protrudes into the via opening during the grinding.

The conductive via may not be completely cured before the grinding. The integrated circuit may be formed within a microelectronic die that is embedded within the substrate. The microelectronic die may have a device surface having an elevation within 10 microns of the first surface of the substrate.

After the grinding, the end of the conductive via may have an elevation within 10 microns of the first surface of the substrate. The protective layer may be water soluble. The method may also include removing the protective layer. The method may also include curing the conductive via.

The invention also provides a method for constructing an electronic assembly. A substrate having upper and lower surfaces and a microelectronic die embedded therein is provided. The microelectronic die has an integrated circuit formed therein. A protective layer is formed over the upper surface of the substrate. The protective layer has a thickness between 5 and 20 microns. A plurality of via openings are formed through the protective layer and into the upper surface of the substrate. Each of the via openings has a depth. A plurality of conductive vias are formed within the via openings. Each of the conductive vias has an end at a first elevation relative to the upper surface of the substrate. The protective layer and the ends of the conductive vias are ground with a polishing element to lower the ends of the conductive vias to a second elevation that is less than the first elevation. The polishing element has a compliance and applies a force onto the protective layer such that a portion of the polishing element protrudes into the via openings during the grinding.

The formation of the conductive vias may include depositing a conductive paste into the via openings. The conductive paste may not be completely cured before the grinding.

The microelectronic die may have a device surface having an elevation within 10 microns of the upper surface of the substrate. The second elevation of each conductive via may be within 10 microns of the upper surface of the substrate. The protective layer may be water soluble and further comprising removing the protective layer.

The invention further provides a method for constructing a microelectronic assembly. A substrate having upper and lower surfaces and a microelectronic die embedded therein is provided. The microelectronic die has a device surface. The device surface has an elevation within 10 microns of the upper surface of the substrate. A protective layer is formed over the upper and lower surfaces of the substrate. The protective layer has a thickness between 5 and 20 microns. A plurality of via openings are formed through the protective layer over the upper surface of the substrate, the substrate, and the protective layer over the lower surface of the substrate. A conductive paste is deposited within the plurality of via openings to form a conductive via within each via opening. Each conductive via has a height that is greater than a combined thickness of the protective layer over the upper surface of the substrate, the substrate, and the protective layer over the lower surface of the substrate and upper and lower opposing ends that extend beyond the protective layer over the respective upper and lower surfaces of the substrate. The protective layer over the upper and lower surfaces of the substrate and the opposing ends of the conductive vias are ground with a polishing element. The polishing element has a compliance and applies a force onto the protective layer such that a portion of the polishing element protrudes into the via openings during the grinding to reduce the height of the conductive vias to less than the combined thickness of the protective layer over the upper surface of the substrate, the substrate, and the protective layer over the lower surface of the substrate and wherein the upper and lower opposing ends of the conductive vias each have an elevation that is within 10 microns of the respective surface of the substrate. The protective layer is removed over the upper and lower surfaces of the substrate. The conductive vias are cured.

The curing of the conductive vias may be performed after the grinding. A second protective layer may be formed over the protective layer and the ends of the conductive vias. The protective layer and the second protective layer may be water soluble. The grinding may be performed with a non-aqueous solvent.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method for constructing an electronic assembly comprising:
providing a substrate having first and second opposing surfaces and an integrated circuit formed therein;
forming a protective layer over the first surface of the substrate;
forming a via opening through the protective layer and into the first surface of the substrate;
forming a conductive via in the via opening, the conductive via having an end at a first elevation relative to the first surface of the substrate; and
grinding the end of the conductive via such that the end of the conductive via is at a second elevation relative to the first surface of the substrate, the second elevation being less than the first elevation.

2. The method of claim 1, wherein the protective layer has a thickness less than 35 microns.

3. The method of claim 2, wherein the thickness of the protective layer is between approximately 5 and 20 microns.

4. The method of claim 3, wherein the grinding of the end of the conductive via includes grinding the protective layer, the grinding is performed with a polishing element having a compliance, and the polishing element applies a force onto the protective layer wherein the compliance and the force are such that a portion of the polishing element protrudes into the via opening during the grinding.

5. The method of claim 4, wherein the conductive via is not completely cured before the grinding.

6. The method of claim 5, wherein the integrated circuit is formed within a microelectronic die that is embedded within the substrate.

7. The method of claim 6, wherein the microelectronic die has a device surface having an elevation within 10 microns of the first surface of the substrate.

8. The method of claim 7, wherein after the grinding the end of the conductive via has an elevation within 10 microns of the first surface of the substrate.

9. The method of claim 8, wherein the protective layer is water soluble and further comprising removing the protective layer.

10. The method of claim 9, further comprising curing the conductive via.

11. A method for constructing an electronic assembly comprising:
providing a substrate having upper and lower surfaces and a microelectronic die embedded therein, the microelectronic die having an integrated circuit formed therein;
forming a protective layer over the upper surface of the substrate, the protective layer having a thickness between 5 and 20 microns;
forming a plurality of via openings through the protective layer and into the upper surface of the substrate, each of the via openings having a depth;
forming a plurality of conductive vias within the via openings, each of the conductive vias having an end at a first elevation relative to the upper surface of the substrate; and
grinding the protective layer and the ends of the conductive vias with a polishing element to lower the ends of the conductive vias to a second elevation that is less than the first elevation, wherein the polishing element has a compliance and applies a force onto the protective layer such that a portion of the polishing element protrudes into the via openings during the grinding.

12. The method of claim 11, wherein the formation of the conductive vias includes depositing a conductive paste into the via openings and wherein the conductive paste is not completely cured before the grinding.

13. The method of claim 12, wherein the microelectronic die has a device surface having an elevation within 10 microns of the upper surface of the substrate.

14. The method of claim 13, wherein the second elevation of each conductive via is within 10 microns of the upper surface of the substrate.

15. The method of claim 14, wherein the protective layer is water soluble and further comprising removing the protective layer.

16. A method for constructing an electronic assembly comprising:
providing a substrate having upper and lower surfaces and a microelectronic die embedded therein, the microelectronic die having a device surface, the device surface having an elevation within 10 microns of the upper surface of the substrate;
forming a protective layer over the upper and lower surfaces of the substrate, the protective layer having a thickness between 5 and 20 microns;
forming a plurality of via openings through the protective layer over the upper surface of the substrate, the substrate, and the protective layer over the lower surface of the substrate;
depositing a conductive paste within the plurality of via openings to form a conductive via within each via opening, each conductive via having a height that is greater than a combined thickness of the protective layer over the upper surface of the substrate, the substrate, and the protective layer over the lower surface of the substrate and upper and lower opposing ends that extend beyond the protective layer over the respective upper and lower surfaces of the substrate;
grinding the protective layer over the upper and lower surfaces of the substrate and the opposing ends of the conductive vias with a polishing element, wherein the grinding element has a compliance and applies a force onto the protective layer such that a portion of the polishing element protrudes into the via openings during the grinding to reduce the height of the conductive vias to less than the combined thickness of the protective layer over the upper surface of the substrate, the substrate, and the protective layer over the lower surface of the substrate and wherein the upper and lower opposing ends of the conductive vias each have an elevation that is within 10 microns of the respective surface of the substrate;
removing the protective layer over the upper and lower surfaces of the substrate; and
curing the conductive vias.

17. The method of claim 16, wherein the curing of the conductive vias is performed after the grinding.

18. The method of claim 17, further comprising forming a second protective layer over the protective layer and the ends of the conductive vias.

19. The method of claim 18, wherein the protective layer and the second protective layer are water soluble.

20. The method of claim 19, wherein the grinding is performed with a non-aqueous solvent.
